(19) United States
(12) Patent Application Publication
(10) Pub. No.: US 2009/0140605 A1
(43) Pub. Date: Jun. 4, 2009

(54) COMPLEX OXIDE FILM AND METHOD FOR PRODUCING SAME, DIELECTRIC MATERIAL INCLUDING COMPLEX OXIDE FILM, PIEZOELECTRIC MATERIAL, CAPACITOR, PIEZOELECTRIC ELEMENT AND ELECTRONIC DEVICE

(75) Inventor: Akihiko Shirakawa, Chiba (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Minato-ku, Tokyo (JP)

(21) Appl. No.: 11/997,052

(22) PCT Filed: Jul. 28, 2006
(86) PCT No.: PCT/JP2006/314999

§ 371 Date: Mar. 3, 2008

(30) Foreign Application Priority Data
Jul. 29, 2005 (JP) 2005-221333

(51) Int. Cl. C01G 23/00; C01B 13/32; C25D 11/18; H01G 4/12; H01G 9/00; H01G 9/052; H01L 41/187; H01L 41/24; H01L 41/08; H01G 4/10

(52) U.S. Cl. 310/311; 427/79; 427/100; 205/229; 428/472.1; 428/337; 428/328; 361/311

(57) ABSTRACT

The invention relates to a method for a complex oxide film having a high relative dielectric constant and a thickness which can be arbitrarily controlled, which is obtained, without using any large-scale equipment, by forming a metal oxide layer containing a first metal element on substrate surface and then allowing the layer to react with a solution containing a second metal ion to thereby form a complex oxide film containing the first and second metal elements, and a production method thereof. Further, the invention relates to a dielectric material and a piezoelectric material containing the complex oxide film, a capacitor and a piezoelectric element including the material, and an electronic device comprising the element.

### TECHNICAL FIELD

The present invention relates to a complex oxide film having a high relative dielectric constant and a production method thereof, a dielectric material containing the complex oxide film, a piezoelectric material, a capacitor including the complex oxide film which is advantageous in increasing electrostatic capacitance, a piezoelectric element, and an electronic device comprising these electronic components.

### BACKGROUND ART

Conventionally, as small-sized, large-capacitance capacitors, multilayer ceramic capacitors, tantalum electrolytic capacitors, and aluminum electrolytic capacitors are in practical use. A multilayer ceramic capacitor, which uses as a dielectric body a complex oxide such as barium titanate having a large relative dielectric constant, involves a thick-film process, which causes thickness of a dielectric layer to be 1 μm or more. Electrostatic capacitance is in inverse proportion to thickness of dielectric layer and therefore, it is difficult to achieve downsizing and increasing the capacitance at the same time.

On the other hand, a tantalum electrolytic capacitor and an aluminum electrolytic capacitor use as dielectric body, tantalum oxide or aluminum oxide which is obtained by subjecting metal tantalum or metal aluminum to anodic oxidation. Since the thickness of the dielectric layer can be controlled by selecting the anodic oxidation voltage, it is possible to obtain a thin dielectric layer having a thickness of 0.1 μm or less. However, both tantalum oxide and aluminum oxide have a small relative dielectric constant as compared with that of a complex oxide such as barium titanate, it is difficult to achieve downsizing and increasing in capacitance.

In order to solve the above problems in conventional techniques, many attempts to form a complex oxide thin film on a substrate have been made. Patent Documents 1 and 2 disclose technique for forming a thin film of barium titanate by chemically forming a metal titanium substrate in a strong alkali solution containing barium ions. Patent Document 3 (related application: U.S. Pat. No. 5,328,718) discloses technique for forming a thin film of barium titanate on a substrate by alkoxide method. Patent Document 4 discloses a technique for forming a composite titanate film, in which a metal titanium substrate is treated in an aqueous solution of alkali metal to thereby form a titanate of alkali metal on the substrate surface and is further treated in an aqueous solution containing other metal ions such as barium ions to thereby substitute the alkali metal with other metals such as barium. Also, Non-Patent Document 1 discloses a technique for obtaining a thin film of barium titanate by hydrothermal-electrochemical technique.

[Patent Document 1]

Japanese Patent Application Laid-Open No. S60-116119

[Patent Document 2]

Japanese Patent Application Laid-Open No. S61-30678

[Patent Document 3]

Japanese Patent Application Laid-Open No. H05-124817

[Patent Document 4]

### Japanese Patent Application Laid-Open No. 2000-206135

[Non-Patent Document 1]

### Japanese Journal of Applied Physics Vol.28, No.11, November, 1989, L2007-L2009

### DISCLOSURE OF INVENTION

### Problems to be Solved by Invention

However, it is difficult to control the thickness of the dielectric layer in the methods described in Patent Document 1 to 4 and the capacitance of an obtained capacitor cannot be controlled. In the method of Non-Patent Document 1, reaction can hardly proceed at a temperature around 100° C. and the method, which requires an autoclave to carry out the reaction under a high pressure, involved large scale equipment.

The object of the present invention, which does not require any complicated or large scale equipment, is to provide a complex oxide film having a high relative dielectric constant and production method thereof where the film thickness can be arbitrarily controlled, a dielectric material and piezoelectric material including the complex oxide film, a capacitor including the materials, a piezoelectric element, and an electronic device comprising the element.

### Means for Solving the Problems

As a result of intensive studies made with a view to solving the problems, the present inventors have found out that the object can be achieved by the following means.

(1) A method for producing a complex oxide film, comprising a step of forming a metal oxide layer containing a first metal element on a substrate surface and a step of allowing a solution containing a second metal ion to react with the metal oxide layer containing the first metal element to form the complex oxide film containing the first and second metal elements.

(2) The method for producing a complex oxide film according to 1, wherein the first metal is titanium.

(3) The method for producing a complex oxide film according to 1 or 2, wherein the second metal is an alkali earth metal or lead.

(4) The method for producing a complex oxide film according to any one of 1 to 3, wherein the substrate is metal titanium or an alloy containing titanium.

(5) The method for producing a complex oxide film according to 4, wherein the metal oxide layer is formed by anodic oxidation of the substrate.

(6) The method for producing a complex oxide film according to any one of 1 to 5, wherein the solution containing a second metal ion is a solution of pH 11 or more.

(7) The method for producing a complex oxide film according to any one of 1 to 6, wherein the solution containing a second metal ion is allowed to react with the first metal oxide layer at 40° C. or higher.

(8) The method for producing a complex oxide film according to any one of 1 to 7, wherein the solution containing a second metal ion contains a basic compound which turns into gas through at least one of evaporation, sublimation and thermal decomposition at atmospheric pressure or under reduced pressure.

(9) The method for producing a complex oxide film according to 8, wherein the basic compound is an organic basic compound.

(10) The method for producing a complex oxide film according to 9, wherein the organic basic compound is tetramethyl ammonium hydroxide.

(11) A complex oxide film produced by the method described in any one of 1 to 10.

(12) A complex oxide film formed on surface of metal titanium or an alloy containing titanium, comprising at least one metal element selected from a group consisting of titanium, an alkali metal and lead.

(13) The complex oxide film according to 12, wherein the metal titanium or an alloy containing titanium is a foil having a thickness of 5 to 300 μm.

(14) The complex oxide film according to 12, wherein the metal titanium or the alloy containing titanium is a sintered body of particles having an average particle size of 0.1 to 20 μm.

(15) The complex oxide film according to any one of 11 to 14, comprising a perovskite compound.

(16) A dielectric material comprising the complex oxide film described in any one of 11 to 15.

(17) A piezoelectric material comprising the complex oxide film described in any one of 11 to 15.

(18) A capacitor comprising the dielectric material described in 16.

(19) A piezoelectric element comprising the piezoelectric material described in 17.

(20) An electronic device comprising the capacitor described in 18.

(21) An electronic device comprising the piezoelectric element described in 19.

### Effects of Invention

According to the production method of the present invention of the complex oxide film, a complex oxide film containing the first and second metal elements can be produced by extremely simple method where an oxide film containing the first metal element is formed to have a predetermined thickness in advance on a substrate surface and then the film is allowed to react with a solution containing the second metal ion. Therefore, the present invention, which does not require any complicated or large scale equipment, enables production of complex oxide film at low cost. Since the film thickness of the oxide film containing the first metal element which is formed in advance and the film thickness of the complex oxide film obtained after the reaction have correlations with types of materials used and production conditions, the complex oxide film can be obtained with a desired film thickness.

By using metal titanium or an alloy containing titanium as substrate and subjecting the substrate to anodic oxidation to form a titanium oxide film, film thickness of the titanium oxide film can be easily controlled. By allowing an aqueous solution containing at least one kind of metal ion selected from alkali earth metals and lead to react with the titanium oxide film, a strong dielectric film having a high relative dielectric constant can be formed.

Here, by using an alkaline solution of pH 11 or more as a solution containing a second metal ion, a strong dielectric film having high crystallinity can be formed, with a high relative dielectric constant. By using as an alkali component in the alkaline solution a basic compound which turns into gas through at least one of evaporation, sublimation and thermal decomposition at atmospheric pressure or under reduced pressure, deterioration in properties of the complex oxide film caused by alkali components remaining in the film can be suppressed, whereby the complex oxide film having stable properties can be obtained. Moreover, by employing a temperature of 40 ° C. or higher, the reaction process can be more ensured.

The thus obtained complex oxide film has a high relative dielectric constant. By using as substrate having a sintered body having a thickness of 5 to 300 μm or consisting of metal-titanium or titanium-containing alloy fine particles of an average particle size of 0.1 to 20 μm, the ratio of the complex oxide film against the substrate can be increased, which makes the complex oxide film more suitable for an electronic part used in a capacitor or the like. Thus, the invention enables downsizing of electronic parts and further downsizing and reduction in weight of electronic devices using such electronic parts.

### BEST MODE FOR CARRYING OUT THE INVENTION

Hereinafter, embodiments of the complex oxide film and production method of the present invention are explained in detail.

The complex oxide film of the present invention can be obtained by a production method comprising a step of forming a metal oxide layer containing a first metal element on a substrate surface and a step of allowing a solution containing a second metal ion to react with the first metal oxide layer to form the complex oxide film containing the first and second metal elements. There is no particular limitation on the material of the substrate and any of conductive material, semiconductive material and insulative material may be used depending on uses. Preferred examples of material suitable for the substrate used in capacitors include metal titanium and alloys containing titanium as conductor. On a substrate made of such a metal, a complex oxide film is formed as a dielectric body so that the metal substrate itself can serve as an electrode of a capacitor. There is no particular limitation on the shape of the substrate, either. The substrate may have a shape of plate or foil and further may have an uneven surface. For the substrate to be used in a capacitor, the larger the surface area per weight is, the larger the ratio of the complex oxide film against the substrate is and the more advantageous. From viewpoints of obtaining this advantage, downsizing and reducing the weight in the capacitor, it is preferable to use a foil-shaped substrate having a thickness of 5 to 300 μm, more preferably 5 to 100 μm, still more preferably 5 to 30 μm. When a foil is used as a substrate, its surface area can be increased by subjecting the foil to chemical etching with fluorinated acid or electrolytic etching in advance to thereby make the surface rough. A sintered body of metal titanium or titanium-containing alloy fine particles having an average particle size of 0.1 to 20 μm, preferably 1 to 10 μm, can be used as well, so that the ratio of the complex oxide film against the substrate may be increased.

A metal oxide layer of a predetermined thickness, containing a first metal element is formed on the substrate surface. There is no particular limitation on formation method of the metal oxide layer. In a case where a metal is employed as a substrate, the metal constituting the substrate may be different from or the same with the first metal element constituting the metal oxide layer. In the former case, for example, dry process such as sputtering method and plasma deposition method may be employed. From a viewpoint of low-cost production, however, it is preferable to employ wet process such as sol-gel method and electrolytic plating. In the latter case, similar methods may be employed, and the layer can be formed also by natural oxidation, thermal oxidation or anodic oxidation of the substrate surface or the like. Particularly preferred is anodic oxidation in that film thickness can be easily controlled by adjusting the voltage. Preferred examples include a case where titanium is used as the first metal element, that is, a titanium oxide film is formed on a substrate surface consisting of metal titanium or an alloy containing titanium. Here the term “titanium oxide” means a general formula TiOₓ·nH₂O (0.5≦×≦2,0≦n≦2). The thickness of the oxide film may be adjusted according to the thickness of the complex oxide film as desired and preferred thickness range of the oxide film is from 1 to 4000 nm, more preferably 5 to 2000 nm.

Here the term “perovskite compound” include typical kinds of perovskite compound having a crystalline structure represented by ABX₃, i.e., those compounds generally represented by BaTiO₃, PbZrO₃, and (PbₓLa₍₁₋ₓ₎) (Zr_{y}Ti_{(1-y)})O₃.

In the anodic oxidation treatment, chemical formation is conducted by immersing a predetermined portion of titanium in a chemical-formation liquid and applying predetermined voltage and current density. In order to stabilize the liquid level of the chemical-formation liquid used for immersion, it is preferable to apply masking material on a predetermined portion when the chemical formation is carried out. As masking material, general heat-resistant resins, preferably heat resistant resins or precursors thereof soluble or swellable in solvents, composition consisting of inorganic fine powder and cellulose resin (see JP-A-H11-80596) can be used, however, the invention is not limited by these materials. Specific examples thereof include polyphenylsulfone (PPS), polyethersulfone(PES), cyanate ester resin, fluororesin (tetrafluoroethylene, tetrafluoroethylene-perfluoroalkylvinylether copolymer), polyimide and derivatives thereof. Preferred among them are polyimide, polyethersulfone, fluororesin and precursors. Most preferred is polyimide, which has a sufficient adhesive property to valve-action metal, fillability in valve-action metal, an excellent insulating property, and is endurable to treatment at a high temperature up to about 450° C. A polyimide sufficiently curable by heat treatment at 200 ° C. or lower, preferably at a low temperature from 100 to 200 ° C. and less susceptible to external impacts such as heat of a dielectric layer on anode foil surface which may cause damage or destruction to the resin can be preferably employed. A preferred range of the average molecular weight of polyimide is from about 1000 to 1,000,000, more preferably from about 2000 to 200,000.

These resins can be dissolved or dispersed in organic solvent and the solid concentration (viscosity) thereof can be easily adjusted to be a solution or dispersion of an arbitrary concentration which is suitable for coating operation. A preferred range of the concentration is from 10 to 60% by mass, more preferably from 15 to 40% by mass. With too low a concentration, the masking line will blur while with too high a concentration, the masking material becomes so sticky that the width of the masking line will be unstable.

Electrolytic oxidation is conducted under the following conditions: electrolysis solution containing at least one selected from acids and/or salts thereof such as phosphoric acid, sulfuric acid, oxalic acid, boric acid, adipic acid and salts thereof is used; the concentration of the electrolysis solution is within a range of 0.1 to 30% by mass; the temperature is within a range of 0 to 90° C.; the current density is within a range of 0.1 to 1000 mA/cm²; the voltage is within a range of 2 to 400 V; time is within a range of 1 millisecond to 400 minutes; and constant-current chemical formation is conducted by using valve-action metal as anode and after the voltage has reached a specified voltage, constant-voltage chemical formation is carried out. More preferred conditions are to be selected from the followings: the concentration of the electrolysis solution is within a range of 1 to 20% by mass; the temperature is within a range of 20 to 80° C.; the current density is within a range of 1 to 400 mA/cm²; the voltage is within a range of 5 to 70 V; and time is from 1 second to 300 minutes.

Next, a solution containing a second metal ion is allowed to react with the above formed metal oxide layer containing the first metal element. By this reaction, the first metal oxide layer is turned into a complex oxide film containing the first and second metal elements. There is no particular limitation on the second metal as long as the metal can react with the first metal oxide to thereby achieve a high relative dielectric constant in the complex oxide film. Preferable examples include alkali earth metals such as calcium, strontium and barium and lead. The first metal oxide layer is reacted with a solution containing at least one of these metal ions. It is preferable that the solution be aqueous. Examples thereof include aqueous solutions of metal compounds such as hydroxide, nitrate salt, acetate salt and chloride. One of these compounds may be used alone or two or more kinds of them may be used in mixture at an arbitrary mixing ratio. Examples thereof include calcium chloride, calcium nitrate, calcium acetate, strontium chloride, strontium nitrate, barium hydroxide, barium chloride, barium nitrate, barium acetate, lead nitrate, and lead acetate.

As a condition for this reaction, it is preferable that reaction be conducted in an alkaline solution where a basic compound is present. The preferred pH of the solution is 11 or more, more preferably 13 or more, particularly preferably 14 or more. With a high pH, the complex oxide film can be obtained with a higher crystallinity. The higher the crstallinity is, the higher the relative dielectric constant can be and the more preferable. It is preferable that the reaction solution be kept in an alkaline state of pH 11 or more, for example, by adding an organic alkali compound. There is no particular limitation on alkali components to be added. Preferred is a substance which can turn into gas at atmospheric pressure or under reduced pressure, through evaporation, sublimation and/or thermal decomposition at the calcination temperature or lower. Preferred examples thereof include TMAH (tetramethylammonium hydroxide) and choline. If an alkali metal hydroxide such as lithium hydroxide, sodium hydroxide or potassium hydroxide is added, alkali metal will remain in the obtained complex oxide film, which may cause deterioration in properties of final products to serve as functional materials such as dielectric material and piezoelectric material. For this reason, the above alkali components such as tetramethylammonium hydroxide are preferred.

It is preferable that in the solution, the total number of moles of the second metal ion be adjusted to be 1 to 1000 times the number of moles of the first metal oxide formed on the substrate surface. To the preferred metal compound, a compound containing at least one element selected from a group consisting of Sn, Zr, La, Ce, Mg, Bi, Ni, Al, Si, Zn, B, Nb, W, Mn, Fe, Cu and Dy may be added, such that the concentration of the element in the complex oxide film after the reaction can be less than 5 mol %.

The thus prepared alkaline solution is allowed to cause reaction while stirred and retained, generally at a temperature of 40° C. to the boiling point of the solution, preferably 80° C. to the boiling point of the solution, under normal pressure. The reaction time is generally 10 minutes or more, preferably 1 hour or more. The obtained sample is subjected to electrodialysis, ion exchange, washing with water, permeation membrane treatment or the like if necessary, to thereby remove impurity ions therefrom. Drying can be carried out generally at normal temperature to 150° C. for 1 to 24 hours. There is no particular limitation on the drying atmosphere and drying can be conducted in the air or under reduced pressure.

A capacitor can be produced by using as anode the substrate having the complex oxide film of the present invention formed thereon. In this case, manganese oxide, electroconductive polymer, and metals such as nickel can be employed as cathode in the capacitor. By attaching carbon paste thereon, electric resistance can be reduced and further silver paste is attached thereon to ensure conduction with an external lead.

The thus obtained capacitor, which uses as a dielectric body the complex oxide film of a preferred embodiment of the present invention having a high relative dielectric constant, can achieve a large electrostatic capacitance. Moreover, the dielectric layer in the capacitor can be thin. By this advantage, the capacitor itself can be downsized and the electrostatic capacitance can be further increased.

Thus downsized capacitors can be suitably used in electronic devices, especially as parts in portable devices such as cellular phones.

### EXAMPLES

Hereinafter, the present invention will be described in more detail with reference to Examples and Comparative Examples, but the present invention is not restricted thereto.

### Example 1

A titanium foil (product of THANK-METAL Co., Ltd.) with purity of 99.9% having a thickness of 20 μm, having been prepared to be 3.3 mm in width, was cut into 13 mm-long rectangular pieces. One short side of each of the titanium foil pieces was fixed to a metal guide by welding. A 0.8 mm-wide line was formed with a solution of polyimide resin (product of UBE INDUSTRIES.LTD.) on a position 7 mm from the unfixed end of the foil, and dried at 180° C. for 30 minutes as preparation for anodic oxidation. The portion of the titanium foil from the unfixed end to the above-formed polyimide resin line was immersed in 5% by mass phosphoric acid aqueous solution to conduct anodic oxidation treatment by applying a voltage of 15 V with electric current density of 30 mA/cm² at 40° C. for 120 minutes, followed by washing with water and drying. Subsequently, the same area was immersed in a solution where barium hydroxide (product of Nihon Solvay K.K.) of moles of 100 times the number of moles of titanium oxide included in the titanium oxide layer was dissolved in 20% tetramethylammonium hydroxide aqueous solution (product of Sacheem Inc.) at 100° C. for 4 hours, to cause reaction. As a result of identification by X-ray diffraction analysis, it was found out that perovskite-type cubical crystal of barium titanate was produced. By TEM (Transmission Electron Microscope) observation of the cross section surface of a sample processed with a FIB (Focused Ion Beam) apparatus, the thickness of the barium titanate layer was found out to be 0.15 μm. The electrostatic capacitance was measured by immersing each foil piece sample up to 4.5 mm from the unfixed end in an electrolyte (10% by mass aqueous ammonium adipate solution), using the metal guide as an anode and a platinum film as a cathode, with the following apparatus and under the following conditions.
Apparatus: LCR meter (product of NF CORPORATION, ZM2353)
Measuring frequency: 120 Hz
Amplitude voltage: 1 V

As a result, electrostatic capacitance of the sample was found out to be as large as 6.1 μF/cm².

### Example 2

A sample with a barium titanate layer was prepared in the same manner as in Example 1 except that strontium hydroxide was used instead of barium hydroxide. As a result of identification by X-ray diffraction analysis, it was found out that perovskite-type cubical crystal of strontium titanate was produced. By TEM observation of the cross section surface of a sample processed with a FIB apparatus, the thickness of the strontium titanate layer was found out to be 0.15 μm. Electrostatic capacitance of the sample was found out to be as large as 4.0 μF/cm².

### Example 3

Titanium powder having a particle size of 10 μm was molded together with a titanium wire having a diameter of 0.3 mm, and calcined at 1500° C. in a vacuum to thereby obtain a disk-shaped titanium sintered body (having a diameter of 10 mm, a thickness of about 1 mm, a pore ratio of 45% and an average pore size of 3 μm). Subsequently, the sintered body was immersed in 5% by mass phosphoric acid aqueous solution and subjected to anodic oxidation treatment by applying a voltage of 15 V with electric current density of 30 mA/cm² at 40° C. for 120 minutes, followed by washing with water and drying. Then, the sintered body was immersed in a solution where barium hydroxide (product of Nihon Solvay K.K.) of moles of 100 times the number of moles of titanium oxide included in the titanium oxide layer was dissolved in 20% tetramethylammonium hydroxide aqueous solution (product of Sacheem Inc.) at 100° C. for 4 hours, to cause reaction.

The capacitance of thus obtained sintered body having a dielectric layer formed thereon was measured by immersing the sintered body in an electrolyte (10% by mass aqueous ammonium adipate solution), using the titanium wire as an anode, and using as a cathode a platinum film having a size of 100 mm×100 mm×0.02 mm provided in the electrolyte at a position 50 mm apart from the sample having the complex oxide layer formed thereon, with the following apparatus and under the following conditions.
Apparatus: LCR meter (product of NF CORPORATION, ZM2353)
Measuring frequency: 120 Hz
Amplitude voltage: 1 V

As a result, the electrostatic capacitance of the sample was found out to be as large as 270 μF.

### Comparative Example 1

A titanium foil (product of THANK-METAL Co., Ltd.) with purity of 99.9% having a thickness of 20 μm, having been prepared to be 3.3 mm in width, was cut into 13 mm-long rectangular pieces. One short side of each of the titanium foil pieces was fixed to a metal guide by welding. A 0.8 mm wide line was formed with a solution of polyimide resin (product of UBE INDUSTRIES.LTD.) onto a position 7 mm from the unfixed end of the foil, and dried at 180° C. for 30 minutes as preparation for anodic oxidation. The portion of the titanium foil from the unfixed end to the above-formed polyimide resin line was immersed in 5% by mass phosphoric acid aqueous solution to conduct anodic oxidation treatment by applying a voltage of 15 V with electric current density of 30 MA/cm² at 40° C. for 120 minutes, followed by washing with water and drying. Subsequently, the same portion was immersed in a solution where 0.1 mol of Ba (NO₃)₂ (barium nitrate) and 1 mol of KOH (potassium hydroxide) were dissolved in 1000 cc of water at 100° C. for 0.5 hours, to cause reaction. As a result of identification by X-ray diffraction analysis, it was found out that perovskite-type cubical crystal of barium titanate was produced. The above-described preparation method was conducted according to the method described in “Patent Document 1”. By TEM observation of the cross section surface of a sample processed with a FIB apparatus, the thickness of the barium titanate layer was found out to be 0.04 μm. The electrostatic capacitance was measured by immersing each foil piece sample up to 4.5 mm from the unfixed end in an electrolyte (10 % by mass aqueous ammonium adipate solution), using the metal guide as an anode and a platinum film as a cathode, with the following apparatus and under the following conditions.
Apparatus: LCR meter (product of NF CORPORATION, ZM2353)
Measuring frequency: 120 Hz
Amplitude voltage: 1 V

As a result, electrostatic capacitance of the sample was unmeasurable because of its high leakage current. It is assumed that leakage current increased probably because the barium titanate layer, extremely thin, was unevenly attached to the foil.

In the Examples, the complex oxide film was used as a dielectric material for a capacitor, but the complex oxide film can be used as a piezoelectric material for a piezoelectric element.

1. A method for producing a complex oxide film, comprising a step of forming a metal oxide layer containing a first metal element on a substrate surface and a step of allowing a solution containing a second metal ion to react with the metal oxide layer containing the first metal element to form the complex oxide film containing the first and second metal elements.

2. The method for producing a complex oxide film according to claim 1, wherein the first metal is titanium.

3. The method for producing a complex oxide film according to claim 1, wherein the second metal is an alkali earth metal or lead.

4. The method for producing a complex oxide film according to claim 1, wherein the substrate is metal titanium or an alloy containing titanium.

5. The method for producing a complex oxide film according to claim 4, wherein the metal oxide layer is formed by anodic oxidation of the substrate.

6. The method for producing a complex oxide film according to claim 1, wherein the solution containing a second metal ion is a solution of pH 11 or more.

7. The method for producing a complex oxide film according to claim 1, wherein the solution containing a second metal ion is allowed to react with the first metal oxide layer at 40° C. or higher.

8. The method for producing a complex oxide film according to claim 1, wherein the solution containing a second metal ion contains a basic compound which turns into gas through at least one of evaporation, sublimation and thermal decomposition at atmospheric pressure or under reduced pressure.

9. The method for producing a complex oxide film according to claim 8, wherein the basic compound is an organic basic compound.

10. The method for producing a complex oxide film according to claim 9, wherein the organic basic compound is tetramethyl ammonium hydroxide.

11. A complex oxide film produced by the method described in claim 1.

12. A complex oxide film formed on surface of metal titanium or an alloy containing titanium, comprising at least one metal element selected from a group consisting of titanium, an alkali metal and lead.

13. The complex oxide film according to claim 12, wherein the metal titanium or an alloy containing titanium is a foil having a thickness of 5 to 300 μm.

14. The complex oxide film according to claim 12, wherein the metal titanium or the alloy containing titanium is a sintered body of particles having an average particle size of 0.1 to 20 μm.

15. The complex oxide film according to claim 11, comprising a perovskite compound.

16. A dielectric material comprising the complex oxide film described in claim 11.

17. A piezoelectric material comprising the complex oxide film described in claim 11.

18. A capacitor comprising the dielectric material described in claim 16.

19. A piezoelectric element comprising the piezoelectric material described in claim 17.

20. An electronic device comprising the capacitor described in claim 18.

21. An electronic device comprising the piezoelectric element described in claim 19.
